(19) United States
(12) Patent Application Publication
(10) Pub. No.: US 2025/0372480 A1
(43) Pub. Date: Dec. 4, 2025

(54) HEAT DISSIPATION FOR HOT SPOTS

(71) Applicant: Taiwan Semiconductor Manufacturing Company, Ltd., Hsin-Chu (TW)

(72) Inventors: Sheng-Han Tsai, Hsinchu (TW); Tsung-Yu Chen, Hsinchu City (TW); Wensen Hung, Hsinchu County (TW); Yen-Pu Chen, Hsinchu (TW)

(21) Appl. No.: 19/280,631

(22) Filed: Jul. 25, 2025

Related U.S. Application Data
(63) Continuation of application No. 18/628,494, filed on Apr. 5, 2024.
(60) Provisional application No. 63/616,249, filed on Dec. 29, 2023.

(51) Int. Cl. H01L 23/38; H10N 19/00

(52) U.S. Cl. CPC H01L 23/38; H10N 19/00

(57) ABSTRACT

A package structure according to the present disclosure includes a package substrate, a package component disposed over the package substrate, a lid disposed over the package substrate and the package component, and an active cooling device embedded in the lid.

### PRIORITY DATA

This application is a continuation application of U.S. patent application Ser. No. 18/628,494, filed Apr. 5, 2024, which claims the benefit of U.S. Provisional Application No. 63/616,249, filed Dec. 29, 2023, each of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

One of the challenges that come with the scaling down of the ICs is impaired thermal performance. Smaller ICs not only may result in a significant temperature rise but also may hinder heat dissipation. In some instances, heat generation may be localized at certain spots, impacting performance and reliability. It is desirable to dissipate heat from these local hot spots efficiently or even on demand.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method of customizing a heat dissipation solution for a package component, according to various aspects of the present disclosure.

FIGS. 2-8 schematically illustrate operations at various steps of the method in FIG. 1, according to various aspects of the present disclosure.

FIGS. 9-16 illustrates cross-sectional views and top views of active cooling devices, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Semiconductor packaging technologies were once just considered backend processes that facilitates chips to interface external circuitry. Times have changed. Computing workloads have evolved so much that brought packaging technologies to the forefront of innovation. Modern packaging provides integration of multiple chips or dies into a single semiconductor device. Depending on the level of stacking, modern semiconductor packages can have a 2.5D structure or a 3D structure. In a 2.5D structure, at least two dies are coupled to a redistribution layer (RDL) structure or an interposer that provides chip-to-chip communication. The at least two dies in a 2.5D structure are not stacked one over another vertically. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. To dissipate heat from a 3D package, a heat sink may be placed on top of the top dies to direct heat upward and away from the top dies.

The present disclosure provides a method of customizing a heat dissipation solution for a package component. In an example, a design of a package component is received. A thermal map of the package component is obtained to identify a local hot spot. A lid that includes an embedded active cooling device is fabricated. When the lid is placed over the package structure, the embedded active cooling device is disposed directly over the local hot spot. After the package component is fabricated, it is bonded to a package substrate. The lid is placed over the package component and the package substrate. The active cooling device may be powered to boost heat dissipation with respect to the local hot spot. The present disclosure also provides embodiments of the active cooling device to be embedded in the lid. The active cooling device according to the present disclosure is electrically powered and is configured to dissipate heat radially away from the local hot spot.

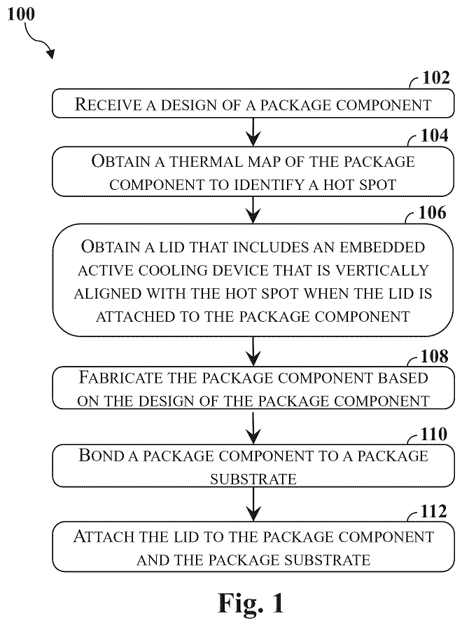

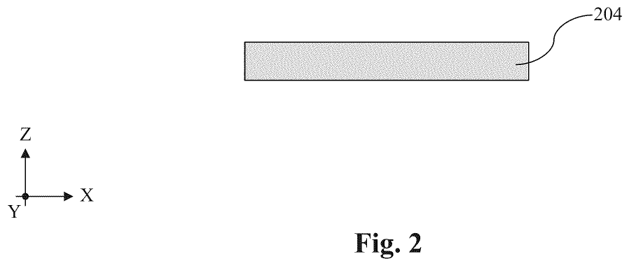

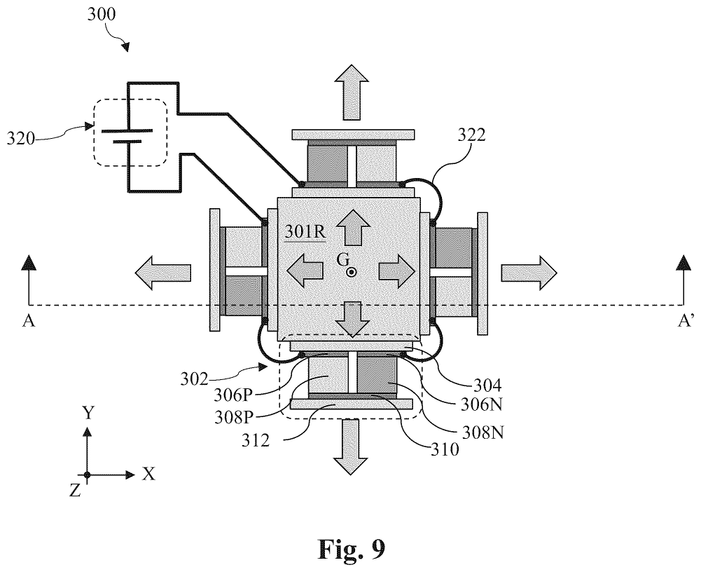

The various aspects of the present disclosure will now be described in more detail with reference to the figures. In that regard, FIG. 1 is a flowchart illustrating method 100 of customizing a heat dissipation solution for a package component, according to various aspects of the present disclosure. Method 100 is merely an example and are not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-8, which schematically illustrate operations at different steps of method 100. FIGS. 9-16 illustrate cross-sectional view and top views of active cooling device according to various aspects of the present disclosure. For avoidance of doubts, the X, Y and Z directions in FIGS. 2-16 are perpendicular to one another. Throughout the present disclosure, unless expressly otherwise described, like reference numerals denote like features.

Referring to FIGS. 1 and 2, method 100 includes a block 102 where a design of a package component 204 is received. In some embodiments, the package component 204 may include a plurality of dies that are bonded on and interconnected by a molding-based interposer, a silicon interposer, a redistribution layer (RDL), or a combination there. The plurality of dies in the package component 204 may be stacked one over the other vertically or bonded side-by-side on a molding-based interposer, a silicon interposer, or a redistribution layer. The plurality of dies in the package component 204 may include a system-on-chip (SoC) die, a logic die, an application specific integrated circuit (ASIC) die, a high bandwidth memory (HBM) die, or a combination thereof. An HBM die may include a plurality of memory dies, such as dynamic random access memory (DRAM) dies. A molding-based interposer may include a local silicon interconnect (LSI) chip and/or an integrated passive device (IPD) embedded in a molding material. The molding-based interposer may also include a plurality of through-interposer-vias (TIVs) extending through the molding-based interposer to provide through-interposer electrical routing. A silicon interposer may include multiple through-substrate-vias (TSVs) extending through the silicon interposer. In some instances, an RDL may be disposed over a surface of the silicon interposer for rerouting. When dies are bonded to a molding-base interposer or a silicon interposer, an underfill is disposed between the dies and the interposer. The dies may be surrounded completely or partially by a molding material. According to the present disclosure, the package component includes dies disposed over its top surface. Each of the dies on the top surface of the package component 204 includes a flip chip bonding. As a result, the dies on the top surface of the package component 204 have back sides of their substrates facing upward. Each of the plurality of dies of the package component 204 includes a plurality of transistors, such as planar transistors, fin-type field effect transistors (FinFETs), gate-all-around (GAA) transistors, nanowire transistors, nanosheet transistors, or other multi-gate transistors.

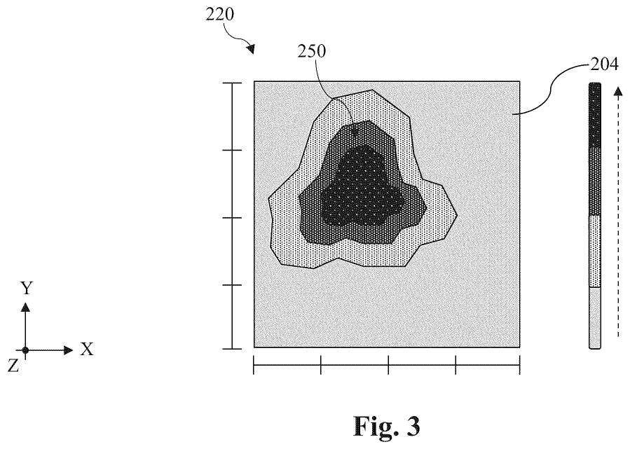

Referring to FIGS. 1 and 3, method 100 includes a block 104 where a thermal map 220 of the package component 204 is obtained to identify a hot spot 250. In one embodiments, the thermal map 220 of the package component 204 is obtained through simulation. In this embodiment, no package component 204 is fabricated and simulation is performed based the design of the package component 204. For example, the simulation may be performed by a computer or a server based on a thermal resistance of the package component 204 in the design, a reference temperature, and a power consumption of the package component. Data generated by the simulation are then compiled into the thermal map 220 shown in FIG. 3. In an alternative embodiment, the thermal map 220 of the package component 204 is obtained through direct measurement. In the alternative embodiment, at least one package component 204 is fabricated according to the design. After the package component 204 is bonded to a test substrate, power is supplied to the package component 204 and a test procedure is performed on the package component 204. In some instances, once a surface temperature of the package component is allowed to reach an equilibrium state, a thermal infrared (IR) sensor or a thermal imaging device may be used to measure surface temperature at different locations over the package component 204. The data from the direct measurement may then be used to generate a thermal map 220 representatively shown in FIG. 3. FIG. 3 includes an isothermal map of the package component 204. In FIG. 3, isotherms or areas assigned a darker shed indicate an area having a higher local temperature. A hot spot 250 may be identified from the thermal map 220 based on a predetermined temperature that is considered or proven harmful to the components. Generally, an area of the hot spot 250 increases when the predetermined temperature is lowered. In some embodiments, the predetermined temperature may between 95° C. and about 105° C. An area of the hot spot 250 may be substantially smaller than a top surface area of the package component 204. In some instances, the area of the hot spot 250 may be less than 50% of the top surface area of the package component 204.

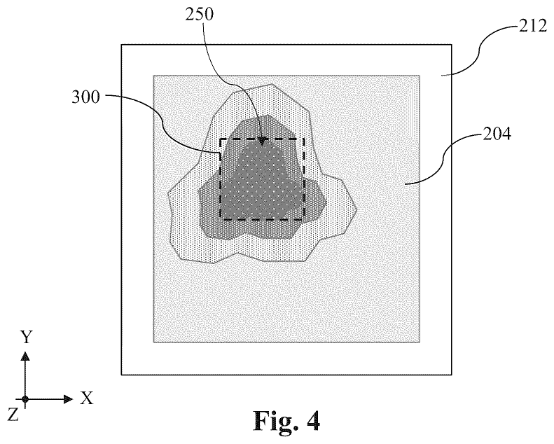

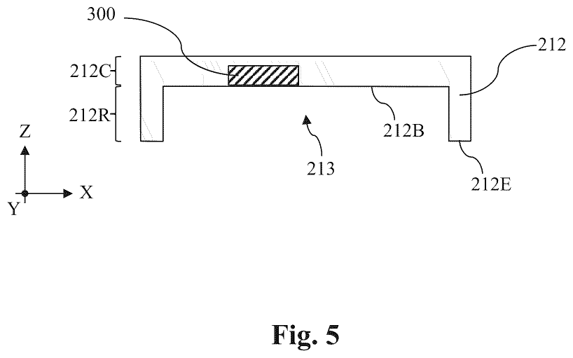

Referring to FIGS. 1, 4 and 5, method 100 includes a block 106 where a lid 212 that includes an embedded active cooling device 300 is obtained. According to some embodiments of the present disclosure, the lid 212 needs to meet at least four criteria. First, the lid 212 should include a cavity to accommodate the package component 204 when the package component 204 is mounted on a package substrate. Referring to FIG. 5, the lid 212 may include a ring portion 212R and a cover portion 212C disposed over the ring portion 212R. In some embodiments, the ring portion 212 is attached to or extends from a perimeter of the cover portion 212C to define a cavity 213 to accommodate the package component 204. Second, the lid 212 should include an active cooling device 300 that is configured to dissipate heat generated from the hot spot 250. In some embodiments represented in FIG. 5, the active cooling device 300 is embedded in the cover portion 212C. A bottom surface of the active cooling device 300 is coplanar with a bottom surface 212B of the lid 212. Referring to FIG. 4, along the Z direction normal to the package component 204, the active cooling device 300 is disposed directly over the hot spot 250 In other words, a vertical projection area of the active cooling device 300 in the lid 212 overlaps a substantial portion of a vertical projection area of the hot spot 250. The vertical alignment between the active cooling device 300 and the hot spot 250 allows the active cooling device 300 to direct its heat dissipation capability accurately to the hot spot 250. Third, the lid 212 is formed of a thermally conductive material and is configured to passively dissipate heat even when the embedded active cooling device 300 is not present. In some embodiments, the lid 212 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. Because the lid 212 is formed of a metal or a metal alloy, it may be referred to as a metal lid 212. Fourth, the lid 212 should provide structural integrity to the package substrate and the package component 204 bonded thereon. Referring to FIG. 5, the lid 212 includes the bottom surface 212B to engage a top surface of the package component 204 and a lower edge 212E to engage the package substrate to which the package component 204 is bonded.

To include the embedded active cooling device 300, a recess may be formed in the cover portion 212C. The active cooling device 300 may be prefabricated and placed in the recess. To ensure good thermal conduction, interfaces between surfaces of the active cooling device 300 and the internal surfaces of the recesses may include thermal interface material (TIM). TIM functions to fill the gaps between the active cooling device 300 and the lid 212 so as to reduce voids and gaps and boost thermal conductivity. TIM between the active cooling device 300 and the lid 212 may be dispensed in a liquid form or as a pre-cut tape. When the TIM is dispensed as a tape, the TIM may include metal (i.e., copper or aluminum), graphite, or graphene. When the TIM is dispensed as a liquid, the TIM may include a base material and a thermal conductive filler. In some instances, the base material for the TIM may include resin or epoxy and the thermal conductive filler for the TIM may include beryllium oxide, aluminum oxide, zinc oxide, aluminum nitride, hexagonal boron nitride, metal (i.e., copper or aluminum), diamond, graphene, or graphite.

As described above, the area of the hot spot 250 may be substantially smaller than the top surface area of the package component 204. Because a vertically projection area of the active cooling device 300 substantially overlaps with a vertical projection area of the hot spot 250, the vertical projection area of the active cooling device 300 may be substantially smaller than the top surface area of the package component 204. In some instances, the vertical projection area of the active cooling device 300 is less than 50% of the top surface area of the package component 204.

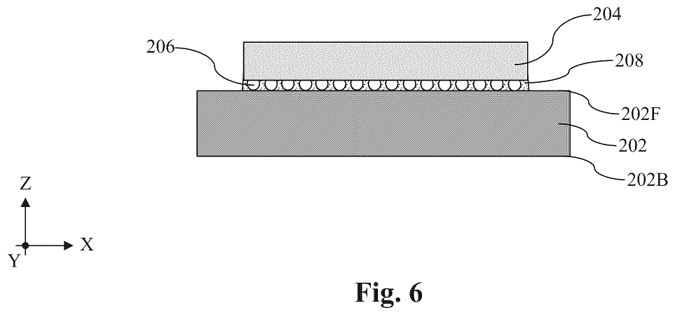

Referring to FIGS. 1 and 6, method 100 includes a block 108 where a package component 204 is fabricated based on the design of the package component 204. As described above, the package component 204 may include a plurality of dies that are bonded on and interconnected by a molding-based interposer, a silicon interposer, a redistribution layer (RDL), or a combination there. To fabricate the package component 204, dies and interposer(s) in the package component 204 are fabricated separately. When the dies are bonded one over another, the dies may be bonded by direct bonding where bonding pads on one dies are aligned to bonding pads on another die. The dies, either bonded one over another or individually, are then bonded to a molding-based interposer, a silicon interposer, a redistribution layer (RDL) by way of connection features, such as micro-bumps. The space between the dies and the interposers are filled with an underfill. A molding material may be deposited around and among the dies.

Referring to FIGS. 1 and 6, method 100 includes a block 110 where the package component 204 is bonded to a package substrate 202. At block 110, the package component 204 is placed over a package substrate 202 such that the connection features 206 are vertically aligned with the contact pads on a frontside surface 202F of the package substrate 202. A reflow process is performed such that the connection features 206 electrically couple the package component 204 to the package substrate 202. After the reflow process, a liquid precursor of an underfill 208 is allowed to fill the gap between the package component 204 and the frontside surface 202F of the package substrate 202 through capillary action. The liquid precursor is then cured by annealing to form the underfill 208. In some embodiments, the connection features 206 may include controlled collapse chip connection (C4) bumps or other solder bumps.

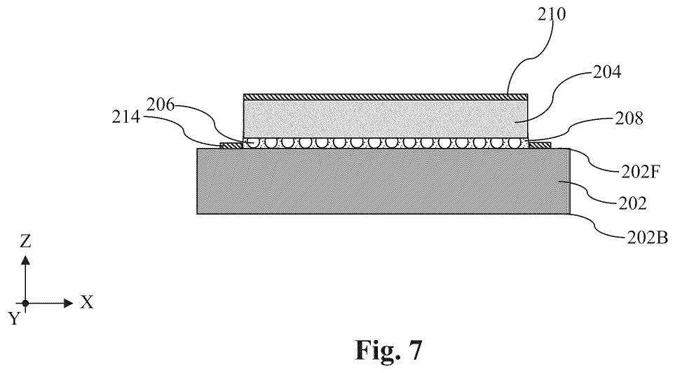

Referring to FIGS. 1, 7 and 8, method 100 includes a block 112 where the lid 212 is attached to the package component 204 and the package substrate 202. Operations at block 112 may include dispensing a thermal interface material (TIM) 210 over a top surface of the package component 204 (shown in FIG. 7), dispensing an adhesive over a top surface of the package substrate 202 (shown in FIG. 7), and placing the lid 212 over the package component 204 and the package substrate 202. Reference is first made to FIG. 7. The TIM 210 is to come between the package component 204 and the lid 212 to improve heat dissipation of the package component 204. Because voids and gaps introduce air in the heat conduction path and air has low thermal conductivity, a function of the TIM 210 is to fill the gaps between the package component 204 and the lid 212 so as to reduce voids and gaps. To facilitate heat conduction, the TIM 210 or a precursor of the TIM 210 should have sufficient thermal conductivity to facilitate heat conduction. To reduce voids and gaps, the TIM 210 or its precursor should possess reasonable flowability or flexibility. According to the present disclosure, the TIM 210 may be dispensed in a liquid form or as a pre-cut tape. When the TIM 210 is dispensed as a tape, the TIM 210 may include metal (i.e., copper or aluminum), graphite, or graphene. When the TIM 210 is dispensed as a liquid, the TIM 210 may include a base material and a thermal conductive filler. In some instances, the base material for the TIM 210 may include resin or epoxy and the thermal conductive filler for the TIM 210 may include beryllium oxide, aluminum oxide, zinc oxide, aluminum nitride, hexagonal boron nitride, metal (i.e., copper or aluminum), diamond, graphene, or graphite.

The adhesive 214 functions to attach the lid 212 to the package substrate 202. Because heat is generated by the package component 204, not the package substrate 202, the adhesive 214 does not play a material role in dissipation of heat. For that reason, the adhesive 214 may not include any thermal conductive filler. In some embodiments, the adhesive 214 may include a base material and a structural filler. In some instances, the base material for the adhesive 214 may include silicone, nylon, epoxy, or resin and the structural filler of the adhesive 214 may include silica or aluminum oxide. The adhesive 214 and the TIM 210 may be dispensed or applied in any order. For example, the TIM 210 is dispensed over the package component 204 and then the adhesive 214 is dispensed over the package substrate 202.

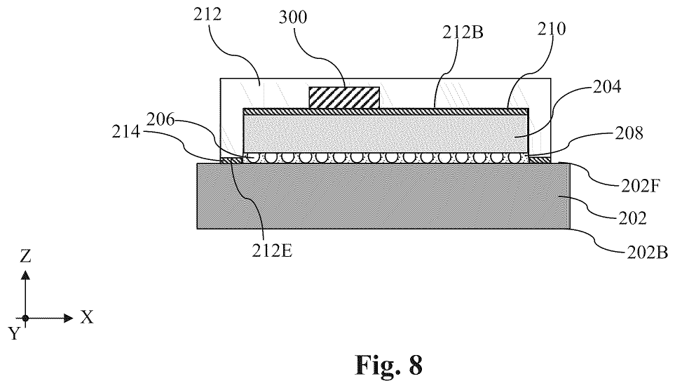

Reference is made to FIG. 8. After the TIM 210 and the adhesive 214 are dispensed over the package component 204 and the package substrate 202, the lid 212 is placed over the package component 204 and the package substrate 202. As shown in FIG. 8, when placed over the package component 204, the package component 204 is received in the cavity 213 (shown in FIG. 5). The bottom surface 212B of the lid 212 engages the top surface of the package component 204 by way of the TIM 210. The lower edge 212E of the lid 212 engages the top surface of the package substrate 202 by way of the adhesive 214.

After the lid 212 is placed over the package substrate 202 and the package component 204, the TIM 210 and the adhesive 214 are cured. In some embodiments, the TIM 210 and the adhesive 214 are thermally cured. In these embodiments, the structure shown in FIG. 8 may be subject to an anneal process. In some embodiments, the anneal process may include an anneal temperature between about 130° C. and about 180° C. In order for the package substrate 202 to be mounted on further substrate, such as a printed circuit board (PCB). Solder features (not shown) may be formed over a backside surface 202B of the package substrate 202. As described above, the package substrate 202 may also include a plurality of contact pads or under bump metallization (UBM) features over the backside surface 202B. Solder features may be formed over the plurality of contact pads tor UBM features. In some embodiments, the solder features may include alloys of tin, lead, silver, copper, nickel, bismuth, or combinations thereof.

FIGS. 9-16 illustrate cross-sectional views and top views of representative embodiments the active cooling device 300. The active cooling device 300 according to the present disclosure includes a base plate to vertically engage the hot spot 250 of the package component 204 by way of the TIM 210. In a top view, the base plate may have a triangular shape, a rectangular shape, a square shape, or a polygonal shape such that the base plate includes multiple sides facing away from a geometric center of the base plate. A thermoelectric cooler (TEC) unit is disposed along each of the multiple sides of the base plate. The TEC units may be powered by a direct current (DC) power source that is controlled by a controller. The TEC units may either be electrically connected in series or in parallel to fit the design requirements. Each of the TEC units has a cold side and a hot side. The cold side of each of the TEC units is coupled to a side of the base plate while the hot side is facing away from the base plate. Configured in this way, the active cooling device 300 may direct heat vertically and radially away from the hot spot 250.

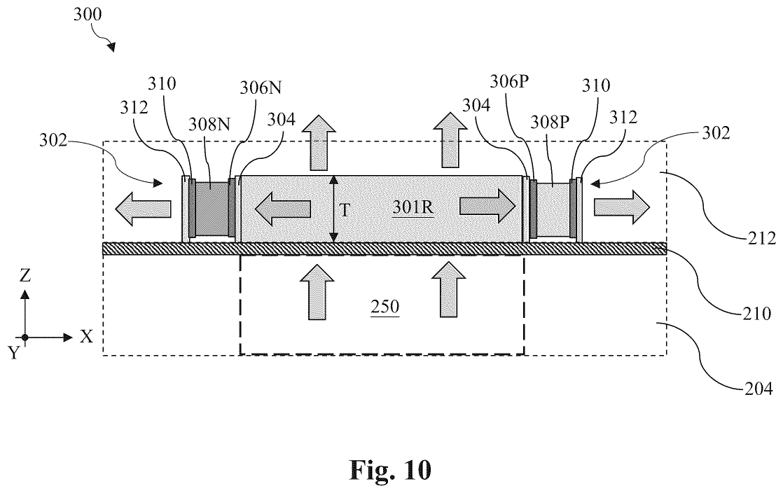

FIG. 9 provides a top view of an active cooling device 300 that includes a rectangular base plate 301R and TEC units that are connected in series. The active cooling device 300 includes a rectangular base plate 301R that has a rectangular shape in the top view shown in FIG. 9. Reference is briefly made to FIG. 10, which provides a cross-sectional view along line A-A′ in FIG. 9. In some embodiments, the rectangular base plate 301R is disposed directly over the hot spot 250. In other word, a vertical projection areas of the rectangular base plate 301R and the hot spot 250 may substantially overlap. By way of the TIM 210, heat from the hot spot 250 may be conducted upward into the rectangular base plate 301R. As illustrated in the cross-sectional view in FIG. 10, the rectangular base plate 301R has a thickness T. In some embodiments, the thickness T may be between about 1 mm and about 6 mm. As indicated by the arrows, the thickness T allows the rectangular base plate 301R to not only conduct heat vertically into the lid 212 over the active cooling device 300 but also radially towards four (4) sides of the rectangular base plate 301R. The radial heat conduction may be said to be away from a geometric center G of the rectangular base plate 301R. The rectangular base plate 301R may be made of a highly thermally conductive material, such as a metal, a metal alloy or a non-metal material. Example metals for the construction of the rectangular base plate 301R may include aluminum (Al), copper (Cu), iron (Fe), nickel (Ni), cobalt (Co), or a combination thereof. Example metal alloys for the construction of the rectangular base plate 301R may include an aluminum-copper alloy, an iron-nickel alloy, or an iron-nickel-cobalt alloy. Example non-metal materials for the rectangular base plate 301R may include beryllium oxide, aluminum oxide, zinc oxide, aluminum nitride, hexagonal boron nitride, diamond, or graphite. A bottom surface of the rectangular base plate 301R is the bottom surface of the active cooling device 300. As described above, the active cooling device 300 is embedded in a horizontal portion of the lid 212 and the bottom surface of the rectangular base plate 301R is level or coplanar with the bottom surface 212B (shown in FIG. 5) of the lid 212.

In some embodiments represented in FIG. 9, a TEC unit 302 is disposed along each of the four (4) sides of the rectangular base plate 301R. The TEC unit 302 is also known in the art as a Peltier cooler and is a solid-state active heat pump. The TEC unit 302 is an active heat pump as it consumes electricity to pump heat from a cold side to a hot side. Because the active cooling device 300 includes more than one of the TEC units 302, the active cooling device 300 consumes electricity and is considered an active cooling device, hence its name. Referring still to FIG. 9, each of the TEC units 302 includes an n-type semiconductor pellet 308N and a p-type semiconductor pellet 308P. Away from the rectangular base plate 301R, the n-type semiconductor pellet 308N and the p-type semiconductor pellet 308P are coupled to a common conductive plate 310. Toward the rectangular base plate 301R, the n-type semiconductor pellet 308N is coupled to an n-side conductive plate 306N and the p-type semiconductor pellet 308P is coupled to a p-side conductive plate 306P. In other words, the n-type semiconductor pellet 308N is sandwiched between the common conductive plate 310 and the n-side conductive plate 306N and the p-type semiconductor pellet 308P is sandwiched between the common conductive plate 310 and the p-side conductive plate 306P. In some embodiments represented in FIG. 9, the common conductive plate 310 is thermally coupled to an outer ceramic plate 312. The n-side conductive plate 306N and the p-side conductive plate 306P are thermally coupled to an inner ceramic plate 304. While FIG. 9 illustrates the inner ceramic plate 304 and the outer ceramic plate 312, they are optional. For example, when the rectangular base plate 301R is formed on a non-metal material such as beryllium oxide, aluminum oxide, zinc oxide, aluminum nitride, hexagonal boron nitride, diamond, or graphite, the inner ceramic plate 304 may be omitted and the n-side conductive plate 306N and the p-side conductive plate 306P are thermally coupled to a side of the rectangular base plate 301R. For another example, when the n-side conductive plate 306N and the p-side conductive plate 306P are insulated from the lid 212, the outer ceramic plate 312 may omitted and the common conductive plate 310 is thermally coupled to inner walls of the recess defined in the lid 212.

To reduce power consumption and lower driving voltage, the common conductive plate 310, the n-side conductive plate 306N and the p-side conductive plate 306P are formed of highly electrically conductive metal. In some embodiments, the common conductive plate 310, the n-side conductive plate 306N and the p-side conductive plate 306P may include copper (Cu), aluminum (Al), silver (Ag), or an alloy thereof. In one embodiment, they include copper (Cu). The p-type semiconductor pellet 308P and the n-type semiconductor pellet 308N may include bismuth telluride (BiTe), lead telluride (PdTe), bismuch selenide (BiSe), bismuth antimony telluride (BiSbTe), bismuth selenium telluride (BiSeTe), bismuth antimonide (BiSb), silicon (Si), silicon germanium (SiGe), germanium (Ge), or alloys thereof. In embodiments where the p-type semiconductor pellet 308P and the n-type semiconductor pellet 308N include silicon (Si), silicon germanium (SiGe), or germanium (Ge), they may include p-type dopants to exhibit p-type conductivity or n-type dopants to exhibit n-type conductivity. P-type dopants may include boron (B). N-type dopants may include phosphorus (P) or arsenic (As). When the p-type semiconductor pellet 308P and the n-type semiconductor pellet 308N include a metal alloy, no n-type or p-type dopants are needed. For example, when the p-type semiconductor pellet 308P and the n-type semiconductor pellet 308N are formed of bismuth telluride, the p-type semiconductor pellet 308P may include bismuth-rich bismuth telluride and the n-type semiconductor pellet 308N may include tellurium-rich bismuth telluride. For another example, the n-type semiconductor pellet 308N may include bismuth antimony telluride (BiSbTe) and the p-type semiconductor pellet 308P may include bismuth selenium telluride (BiSeTe). In this example, both bismuth antimony telluride (BiSbTe) and bismuth selenium telluride (BiSeTe) are considered alloys. In this sense, antimony and selenium are not considered dopants. The inner ceramic plate 304 and outer ceramic plate 312 are formed of insulative ceramic materials when they are present. In some embodiments, the inner ceramic plate 304 and outer ceramic plate 312 may include beryllium oxide, aluminum oxide, zinc oxide, aluminum nitride, hexagonal boron nitride, diamond, or graphite. In one embodiment, the inner ceramic plate 304 and outer ceramic plate 312 include beryllium oxide.

In order for each of the TEC units 302 to operate, a power supply 320 causes a current to flow from the n-side conductive plate 306N to the p-side conductive plate 306P. The electrical current flows through the n-type semiconductor pellet 308N, the common conductive plate 310 and the p-type semiconductor pellet 308P. A direction of a flow or electrons is from p-side conductive plate 306P to the n-side conductive plate 306N. FIG. 9 illustrates that the four TEC units 302 are connected in series. Electrical current flows from one TEC unit 302 to another TEC unit 302 along an adjacent side of the rectangular base plate 301R by way of a trace 322. Each of the traces 322 shown in FIG. 9 electrically connects a p-side conductive plate 306P and an n-side conductive plate 306N. Because the p-side conductive plate 306P and the n-side conductive plate 306N cannot be shorted together, the inner ceramic plate 304 is necessary when the rectangular base plate 301R is made of an electrically conductive material. When the rectangular base plate 301R is formed of insulative non-metal, the inner ceramic plate 304 may be omitted. In some embodiments, in order to keep a DC voltage of the power supply 320 below 20V, such as 10 V or 15 V, an overall resistance of the TEC units 302 in FIG. 9 is between about 4 ohm and about 10 ohm.

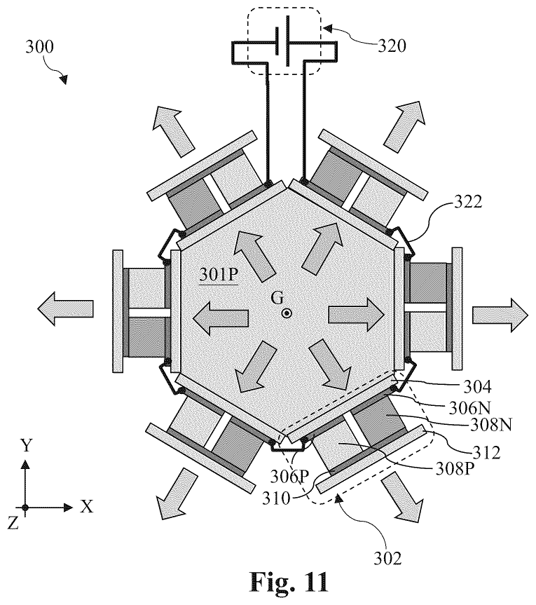

FIG. 11 provides a top view of an active cooling device 300 that includes a polygonal base plate 301P and TEC units connected in series. Instead of a rectangular base plate 301R shown in FIGS. 9 an 10, the active cooling device 300 in FIG. 11 includes a polygonal base plate 301P. For illustration purposes and not for limitation, the polygonal base plate 301P in FIG. 11 is a hexagonal base plate having a rectangular shape in a top view and 6 sides. It should be understood that the polygonal base plate 301P may have other polygonal shape and include less than or more than 6 sides. While not separately shown in a cross-sectional view, the polygonal base plate 301P also has a thickness T (shown in FIG. 10), which may be between 2 mm and about 10 mm. Like the rectangular base plate 301R in FIG. 10, the polygonal base plate 301P is disposed directly over the hot spot 250 when the lid 212 is attached to the package component 204. In other words, vertical projection areas of the polygonal base plate 301P and the hot spot 250 substantially overlap. As the polygonal base plate 301P shown in FIG. 11 has six (6) side surfaces, the active cooling device 300 in FIG. 11 includes six (6) instead of four (4) TEC units 302. The structures and construction of the TEC units 302 have been described in detail above in conjunction with FIGS. 9 and 10 and will not be repeated here. The TEC units 302 have their cold sides facing toward the side surfaces of the polygonal base plate 301P and hot sides facing away from the side surfaces of the polygonal base plate 301P. This configuration allows the active cooling device 300 to direct heat radially away from a geometric center G of the polygonal base plate 301P. In some embodiments represented in FIG. 11, the six (6) TEC units 302 are connected in series and powered by the power supply 320. In order to keep a DC voltage of the power supply 320 below 20V, such as 10 V or 15 V, an overall resistance of the TEC units 302 in FIG. 11 is between about 4 ohm and about 10 ohm.

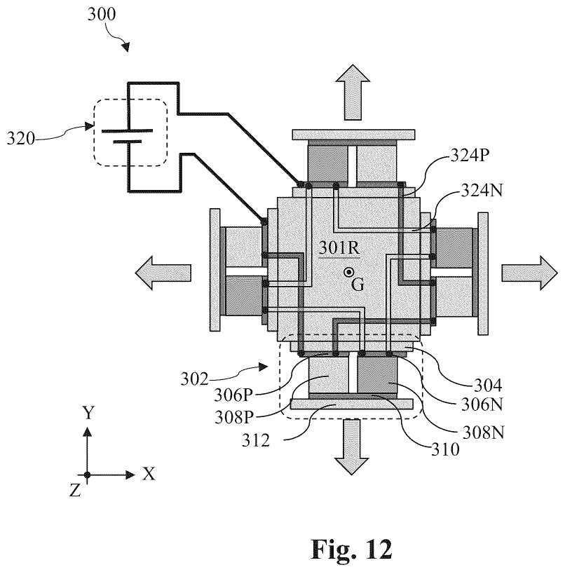

FIG. 12 provides a top view of an active cooling device 300 that includes a rectangular base plate 301R and TEC units connected in parallel. In some embodiments, the TEC units 302 may be electrically connected in parallel to lower voltage and increase current. The active cooling device 300 in FIG. 12 includes a rectangular base plate 301R. The n-side conductive plates 306N of the four (4) TEC units 302 are electrically coupled together by n-side interconnect wires 324N to a positive voltage output of the power supply 320 and the p-side conductive plates 306P of the four (4) TEC units 302 are electrically coupled together p-side interconnect wires 324P to a negative voltage output of the power supply 320. In some embodiments represented in FIG. 12, when the active cooling device 300 includes a rectangular base plate 301R, the active cooling device 300 may include four (4) n-side interconnect wires 324N and four (4) p-side interconnect wires 324P. The shapes and locations of the n-side interconnect wires 324N and p-side interconnect wires 324P shown in FIG. 12 are examples. They may not have a 90-degree bend and may be substantially straight or curved in shape. To reduce power consumption, the n-side interconnect wires 324N and p-side interconnect wires 324P are formed of highly electrically conductive materials, such as copper (Cu), aluminum (Al), silver (Ag), or an alloy thereof.

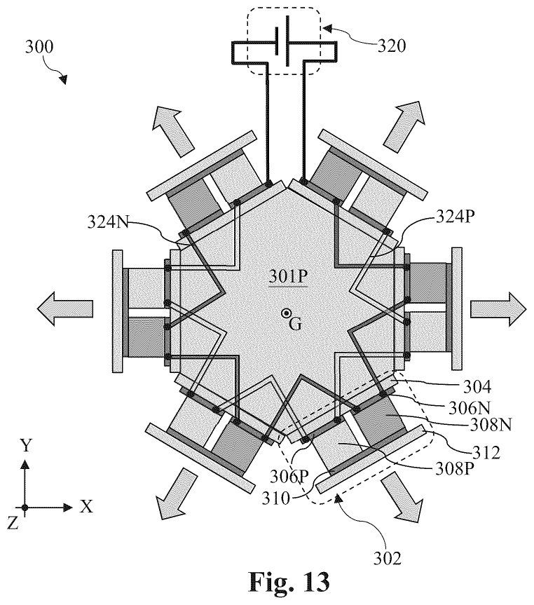

FIG. 13 provides a top view of an active cooling device 300 that includes a polygonal base plate 301P and TEC units connected in parallel. In some embodiments, the TEC units 302 may be electrically connected in parallel to lower voltage and increase current. The active cooling device 300 in FIG. 13 includes a polygonal base plate 301P. The n-side conductive plates 306N of the six (6) TEC units 302 are electrically coupled together by n-side interconnect wires 324N to a positive voltage output of the power supply 320 and the p-side conductive plates 306P of the six (6) TEC units 302 are electrically coupled together by p-side interconnect wires 324P to a negative voltage output of the power supply 320. In some embodiments represented in FIG. 13, when the active cooling device 300 includes a polygonal base plate 301P, the active cooling device 300 may include six (6) n-side interconnect wires 324N and six (6) p-side interconnect wires 324P.

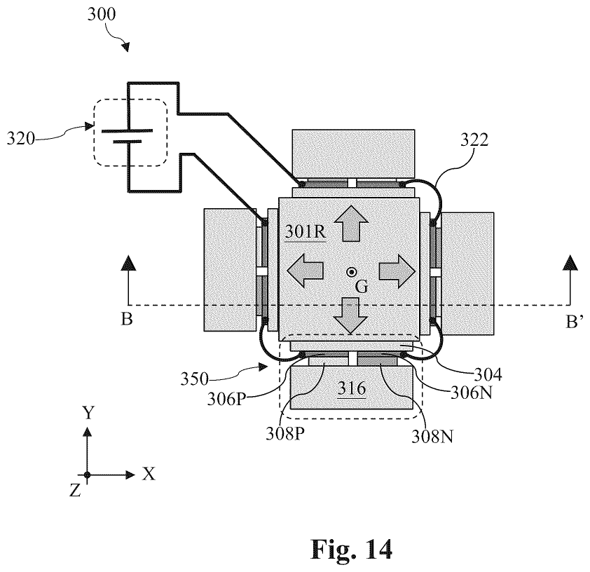

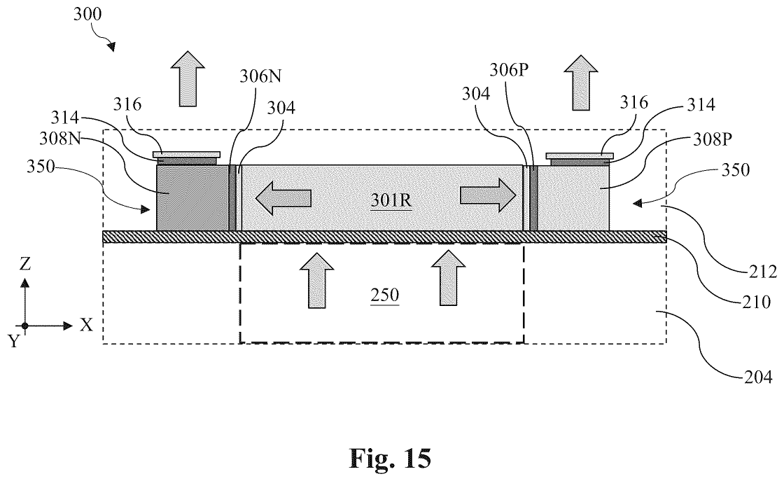

FIG. 14 provides a top view of an active cooling device 300 that includes a rectangular base plate 301R and TEC units having thermal conduction plates facing upwards. In active cooling devices 300 shown in FIGS. 9-13, the cold sides of the TEC units 302 are facing the rectangular base plate 301R or the polygonal base plate 301P and the hot sides of the TEC units 302 are opposing the cold sides and facing away from the rectangular base plate 301R or the polygonal base plate 301P. That configuration the TEC unit 302 to absorb heat from a sidewall of the rectangular base plate 301R or the polygonal base plate 301P and then radially radiate or conductive heat away from a geometric center G of the rectangular base plate 301R or the polygonal base plate 301P. FIG. 14 illustrates an active cooling device 300 that includes elbow TEC units 350 coupled to four (4) sides of a rectangular base plate 301R. Reference is first made to FIG. 14. Like the TEC units 302, each of the elbow TEC units 350 includes an inner ceramic plate 304, an n-type semiconductor pellet 308N, a p-type semiconductor pellet 308P, an n-side conductive plate 306N, and a p-side conductive plate 306P. Reference is now made to FIG. 15, which provides a cross-sectional view along line B-B′ in FIG. 14. Rather than a common conductive plate 310 attached to an end surface of the n-type semiconductor pellet 308N and the p-type semiconductor pellet 308P, the elbow TEC unit 350 includes a top conductive plate 314 thermally coupled to top surfaces of the n-type semiconductor pellet 308N and the p-type semiconductor pellet 308P. The elbow TEC unit 350 also includes a top ceramic plate 316 thermally coupled to the top conductive plate 314. Like the common conductive plate 310, the top conductive plate 314 may include copper (Cu), aluminum (Al), silver (Ag), or an alloy thereof. In one embodiment, the top conductive plate 314 includes copper (Cu). The top ceramic plate 316 may include beryllium oxide, aluminum oxide, zinc oxide, aluminum nitride, hexagonal boron nitride, diamond, or graphite. In one embodiment, the top ceramic plate 316 may include beryllium oxide. As described above, when the rectangular base plate 301R is formed of a non-metal material, such as such as beryllium oxide, aluminum oxide, zinc oxide, aluminum nitride, hexagonal boron nitride, diamond, or graphite, the inner ceramic plates 304 of the elbow TEC units 350 may be omitted. When the n-side conductive plate 306N and the p-side conductive plate 306P are insulated from the lid 212, the top ceramic plate 316 may be omitted. Omission of the top ceramic plate 316 allows the top conductive plate 314 to contact the lid 212 for better thermal conduction. If the n-side conductive plate 306N and the p-side conductive plate 306P are not insulated from the lid 212, the power supply 320 would see a short circuit.

For the TEC units 302 described above, the cold sides are directly opposing the hot side to facilitate a linear thermal pumping radially away from a geometric center G of the rectangular base plate 301R or the polygonal base plate 301P. As shown in FIG. 15, the cold side and the hot side of the elbow TEC unit 350 are not aligned. That is, the normal directions of the inner ceramic plate 304 and the top ceramic plate 316 are not aligned. Similarly, normal directions of the n-side conductive plate 306N (or p-side conductive plate 306P) and the top conductive plate 314 are not aligned. Instead, they form a 90 degree angle. As shown in the arrows in FIG. 15, each of the elbow TEC unit 350 can absorb heat radially away from a sidewall of the rectangular base plate 301R and then radiate or conduct heat vertically away from the rectangular base plate 301R. The top ceramic plate 316 or the top conductive plate 314 may be thermally coupled to the lid 212.

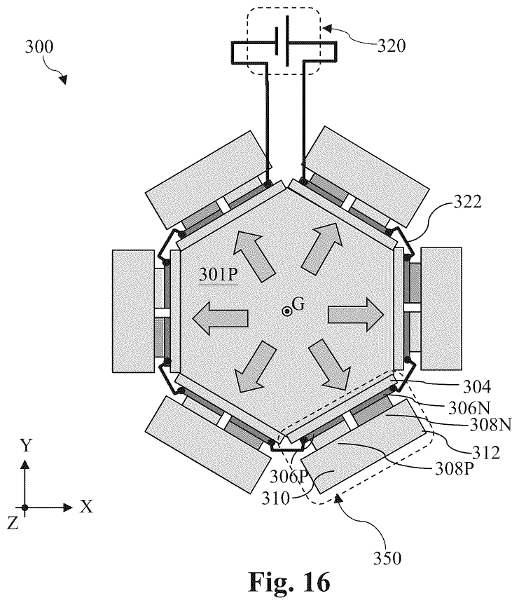

FIG. 16 provides a top view of an active cooling device 300 that includes a polygonal base plate 301P and TEC units having thermal conduction plates facing upwards. FIG. 16 illustrates an active cooling device 300 that includes elbow TEC units 350 coupled to six (6) sides of a polygonal base plate 301P. As described above in conjunction with FIGS. 14 and 15, each of the elbow TEC units 350 is configured to pump heat radially away from a sidewall of the polygonal base plate 301P and vertically towards the lid 212 over the active cooling device 300.

The present disclosure provides many embodiments. In one aspect, the present disclosure provides a package structure. The package structure includes a package substrate, a package component disposed over the package substrate, a lid disposed over the package substrate and the package component, and an active cooling device embedded in the lid.

In some embodiments, the lid includes a lower edge and a bottom surface. The lower edge is attached to a top surface of the package substrate by way of an adhesive. The bottom surface is attached to a top surface of the package component by way of a thermal interface material layer. In some embodiments, the active cooling device includes a bottom surface and the bottom surface of the active cooling device is coplanar with the bottom surface of the lid. In some embodiments, the package component includes a local hot spot and the active cooling device is disposed directly over the local hot spot. In some embodiments, the active cooling device is powered by a direct current (DC) power source. In some embodiments, the package component includes a top surface area and a vertical projection area of the active cooling device is less than 50% of the top surface area. In some embodiments, the active cooling device includes a base plate having a plurality of sidewalls and a plurality of thermoelectric cooling units disposed along the plurality of sidewalls, respectively, Each of the plurality of thermoelectric cooling units includes a first thermal conduction plate thermally coupled to the base plate, a common conductor in contact with the first thermal conduction plate, an n-type semiconductor feature and a p-type semiconductor feature disposed on the common conductor, a first conductor in contact with the n-type semiconductor feature, a second conductor in contact with the p-type semiconductor feature, and a second thermal conduction plate in contact with the first conductor and the second conductor. In some embodiments, the plurality of thermoelectric cooling units are connected in parallel. In some embodiments, the plurality of thermoelectric cooling units are connected in series.

In another aspect, the present disclosure provides a package structure. The package structure includes a cover portion, a ring portion extending continuously from a bottom surface of the cover portion to define a cavity configured to receive a package component, and an active cooling device embedded in the cover portion. A bottom surface of the active cooling device and a bottom surface of the cover portion are coplanar.

In some embodiments, the active cooling device is powered by a direct current (DC) power source. In some embodiments, the bottom surface of the cover portion includes a surface area and a vertical projection area of the active cooling device is less than 50% of the surface area. In some embodiments, the active cooling device includes a base plate having a plurality of sidewalls and a plurality of thermoelectric cooling units disposed along the plurality of sidewalls, respectively. Each of the plurality of thermoelectric cooling units includes a first thermal conduction plate thermally coupled to the base plate, a common conductor in contact with the first thermal conduction plate, an n-type semiconductor feature and a p-type semiconductor feature disposed on the common conductor, a first conductor in contact with the n-type semiconductor feature, a second conductor in contact with the p-type semiconductor feature, and a second thermal conduction plate in contact with the first conductor and the second conductor. In some embodiments, the plurality of thermoelectric cooling units are connected in parallel. In some embodiments, the plurality of thermoelectric cooling units are connected in series.

In still another aspect, the present disclosure provides a method. The method includes receiving a design of a package component, obtaining a thermal map of the package component to identify a local hot spot, and fabricating a lid that includes an embedded active cooling device that is vertically aligned with the local hot spot when the lid is attached to the package component.

In some embodiments, the obtaining includes performing a simulation based on the design of the package component. In some implementations, the obtaining includes fabricating the package component based on the design of the package component, and measure temperatures at different locations of a top surface of the package component during operation of the package component. In some embodiments, the method further includes fabricating the package component based on the design of the package component, bonding the package component to a package substrate, and attaching the lid to the package component and the package substrate. In some embodiments, the attaching includes depositing a thermal interface material layer over the package component, dispensing an adhesive over the package substrate, placing the lid over the package component and the package substrate such that a bottom surface of the lid interfaces the package component by way of the thermal interface material layer and a lower edge of the lid interfaces the package substrate by way of the adhesive, and curing the thermal interface material layer and the adhesive.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus, comprising:
a lid comprising:
a cover portion, and
a ring portion extending from a perimeter of the cover portion; and
an active cooling device embedded in the cover portion,
wherein the lid is configured to receive a package component such that the active cooling device is disposed directly over a hot spot of the package component when the package component is received in the lid,
wherein the active cooling device is powered by a direct current (DC) power source.

2. The apparatus of claim 1, wherein the lid comprises aluminum (Al), copper (Cu), iron (Fe), nickel (Ni), cobalt (Co), or an alloy thereof.

3. The apparatus of claim 1,
wherein the package component comprises a top surface area,
wherein a vertical projection area of the active cooling device is less than 50% of the top surface area.

4. The apparatus of claim 1,
wherein the active cooling device comprises:
a base plate comprising a plurality of sidewalls, and
a plurality of thermoelectric cooling units disposed along the plurality of sidewalls, respectively.

5. The apparatus of claim 4, wherein the base plate comprises aluminum (Al), copper (Cu), iron (Fe), nickel (Ni), cobalt (Co), an aluminum-copper alloy, an iron-nickel alloy, an iron-nickel-cobalt alloy, beryllium oxide, aluminum oxide, zinc oxide, aluminum nitride, hexagonal boron nitride, diamond, or graphite.

6. The apparatus of claim 4, wherein each of the plurality of thermoelectric cooling units comprises:
a first ceramic plate thermally coupled to one of the plurality of sidewalls of the base plate;
a first conductive plate coupled to the first ceramic plate;
a second conductive plate coupled to the first ceramic plate;
an n-type semiconductor pellet coupled to the first conductive plate;
a p-type semiconductor pellet coupled to the second conductive plate;
a common conductive plate disposed over and interfacing top surfaces of the n-type semiconductor pellet and the p-type semiconductor pellet; and
a second ceramic plate disposed on the common conductive plate.

7. The apparatus of claim 6, wherein the first ceramic plate and the second ceramic plate comprise beryllium oxide, aluminum oxide, zinc oxide, aluminum nitride, hexagonal boron nitride, diamond, or graphite.

8. The apparatus of claim 6, wherein the first conductive plate, the second conductive plate and the common conductive plate comprise copper (Cu), aluminum (Al), silver (Ag), or an alloy thereof.

9. The apparatus of claim 6,
wherein the n-type semiconductor pellet comprises a semiconductor material and an n-type dopant, and
wherein the p-type semiconductor pellet comprises the semiconductor material and a p-type dopant.

10. The apparatus of claim 6,
wherein the n-type semiconductor pellet comprises tellurium-rich bismuth telluride or bismuth antimony telluride, and
wherein the p-type semiconductor pellet comprises bismuth-rich bismuth telluride or bismuth selenium telluride.

11. An apparatus, comprising:
a lid comprising:
a cover portion, and
a ring portion extending from a perimeter of the cover portion; and
an active cooling device embedded in the cover portion,
wherein the lid is configured to receive a package component such that the active cooling device is disposed directly over a hot spot of the package component when the package component is received in the lid,
wherein the active cooling device comprises:
a base plate comprising a plurality of sidewalls, and
a plurality of thermoelectric cooling units disposed along the plurality of sidewalls, respectively.

12. The apparatus of claim 11, wherein the active cooling device is powered by a direct current (DC) power source.

13. The apparatus of claim 11, wherein the base plate comprises aluminum (Al), copper (Cu), iron (Fe), nickel (Ni), cobalt (Co), an aluminum-copper alloy, an iron-nickel alloy, an iron-nickel-cobalt alloy, beryllium oxide, aluminum oxide, zinc oxide, aluminum nitride, hexagonal boron nitride, diamond, or graphite.

14. The apparatus of claim 11, wherein the base plate comprises a thickness between about 1 mm and about 6 mm.

15. The apparatus of claim 11, wherein the plurality of thermoelectric cooling units are connected in parallel.

16. The apparatus of claim 11, wherein the plurality of thermoelectric cooling units are connected in series.

17. An apparatus, comprising:
a lid comprising:
a cover portion, and
a ring portion extending from a perimeter of the cover portion; and
an active cooling device embedded in the cover portion,
wherein the lid is configured to receive a package component such that the active cooling device is disposed directly over a hot spot of the package component when the package component is received in the lid,
wherein the active cooling device comprises:
a base plate comprising a plurality of sidewalls, and
a plurality of thermoelectric cooling units disposed along the plurality of sidewalls, respectively,
wherein each of the plurality of thermoelectric cooling units comprises:
a first ceramic plate thermally coupled to one of the plurality of sidewalls of the base plate,
a first conductive plate coupled to the first ceramic plate,
a second conductive plate coupled to the first ceramic plate,
an n-type semiconductor pellet coupled to the first conductive plate,
a p-type semiconductor pellet coupled to the second conductive plate,
a common conductive plate disposed over and interfacing top surfaces of the n-type semiconductor pellet and the p-type semiconductor pellet, and
a second ceramic plate disposed on the common conductive plate.

18. The apparatus of claim 17, wherein the base plate comprises aluminum (Al), copper (Cu), iron (Fe), nickel (Ni), cobalt (Co), an aluminum-copper alloy, an iron-nickel alloy, an iron-nickel-cobalt alloy, beryllium oxide, aluminum oxide, zinc oxide, aluminum nitride, hexagonal boron nitride, diamond, or graphite.

19. The apparatus of claim 17,
wherein the first ceramic plate and the second ceramic plate comprise beryllium oxide, aluminum oxide, zinc oxide, aluminum nitride, hexagonal boron nitride, diamond, or graphite,
wherein the first conductive plate, the second conductive plate and the common conductive plate comprise copper (Cu), aluminum (Al), silver (Ag), or an alloy thereof.

20. The apparatus of claim 17,
wherein the n-type semiconductor pellet comprises a semiconductor material and an n-type dopant, and
wherein the p-type semiconductor pellet comprises the semiconductor material and a p-type dopant.
